(19) United States
(12) Patent Application Publication
(10) Pub. No.: US 2014/0139230 A1
(43) Pub. Date: May 22, 2014

(54) METHOD AND APPARATUS FOR DETERMINING A CHARGE STATE

(71) Applicant: Infineon Technologies AG, Neubiberg (DE)

(72) Inventors: Christoph UNTERRIEDER, Klagenfurt (AT); Stefano MARSILI, Faak am See (AT); Florian HUS, Klagenfurt (AT)

(73) Assignee: Infineon Technologies AG, Neubiberg (DE)

(21) Appl. No.: 14/084,603

(22) Filed: Nov. 19, 2013

(30) Foreign Application Priority Data
Nov. 19, 2012 (DE) 10 2012 111 086.7

(51) Int. Cl. G01R 31/36

(52) U.S. Cl. CPC G01R 31/3606
USPC 324/426

(57) ABSTRACT

Described are methods and devices by which a charge state of a battery can be determined. The determination is made in various embodiments by substantially separating a load, and detecting voltages associated with the battery, and by including adjustments based on operating conditions of the battery.

### RELATED APPLICATIONS

This Application claims priority benefit of German Patent Application 10 2012 111 086.7, which was filed on Nov. 19, 2012. The entire contents of the German Patent Application are hereby incorporated herein by reference.

### BACKGROUND

The description of the present application relates to methods and apparatuses for determining a charging state of a battery, for example a rechargeable battery, and to devices comprising such methods and apparatuses.

A battery, such as a rechargeable battery or a nonrechargeable battery, may be the power supply of mobile portable devices such as mobile phones, portable computers, and the like. Batteries may also be used to power technical equipment such as vehicles. Batteries, whether rechargeable or nonrechargeable, may also generally be referred to the accumulators. Regardless of the type of battery use in a particular device or apparatus, it is often desirable to know the charging status of the used battery. In particular, it is beneficial to be able to properly ascertain a level charge associated with a given battery, so that the battery may be recharged and/or replaced before an associated device or apparatus fails because a sufficient power is not being provided by the battery.

Conventionally, in particular applications, a charge condition of a battery may be determined by measuring a voltage state of the battery while no load or a minimal load is coupled to the battery. For example, a charge condition of a battery may be determined by measuring a voltage state of the battery while no current or very low current is being drawn from the battery. However, it may be a problem to determine a charge condition of the battery during a normal operation state of the device coupled to the battery. That is, determining a proper charge condition of the battery, as indicated in the foregoing, generally requires a low terminal voltage associated with the battery and/or that no load or a minimal load is coupled to the battery. This is very difficult to achieve while a device coupled to the battery.

### BRIEF DESCRIPTION OF THE DRAWINGS

The detailed description is described with reference to the accompanying figures. In the figures, the-most digit(s) of a reference number identifies the figure in which the reference number first appears. The use of the same reference number in different instances in the description and the figures may indicate similar or identical items.

FIG. 1 illustrates a block diagram of an apparatus according to at least one embodiment.

FIG. 2 illustrates a block diagram of an apparatus according to at least one embodiment.

FIG. 3 illustrates a block diagram of an apparatus according to at least one embodiment.

FIG. 4 illustrates a flow diagram of a method according to at least one embodiment.

FIG. 5 illustrates a flow diagram of a method according to at least one embodiment.

FIG. 6 illustrates graphs that show an influence of a terminal voltage over time.

FIG. 7 illustrates a graph illustrating approximate values associated with an open terminal voltage, according to at least one embodiment.

FIG. 8 illustrates a graph illustrating an open terminal voltage in response to a charge state at three different temperatures.

### DETAILED DESCRIPTION

At least one embodiment provides methods and apparatuses which enable determining a state of charge of a battery in a short time with sufficient accuracy.

Exemplary embodiments are described in greater detail with reference to the figures. The invention is not limited to the specifically described embodiments but can be suitably modified and altered. Individual features and feature combinations of one embodiment can be customized with features and feature combinations of other one or more embodiments, unless this is expressly excluded.

Before the following embodiments with reference to the figures are explained in detail, it should be noted that matching elements are provided in the figures with matching or similar reference numerals. In some cases, the description of such matching or similar reference numerals will not repeated. In addition, the figures are not necessarily shown to scale, since their focus is on the illustration and explanation of basic principles.

The method described and the operations or events shown are not necessarily executed in the order shown, but in other embodiments, other orders and/or concurrently performing various operations or events are possible.

In various embodiments, a stationary value of a terminal voltage is approximately determined by the terminal voltage of a battery immediately after the beginning of low load current condition, i.e. a load current below a threshold value. In particular, prior to reaching a steady state, the approximate value of the terminal voltage may be measured one or more times to aid in determining a charge state of the battery.

In one embodiment, a charge state of the battery may be determined based on the basis of correction of the battery operating conditions, such as information on previous loading and/or unloading, for example, based on charging current and/or voltage across the battery during charging and/or discharge status or information on a temperature, a degree of aging, heat transfer, or heat generation of the battery. It should be noted that in the context of one more embodiments, a charging current can be negative or positive depending on whether the battery is charged or discharged by the charging current. Therefore, the concept of charging current may include currents that charge the battery as well as currents that drain the battery.

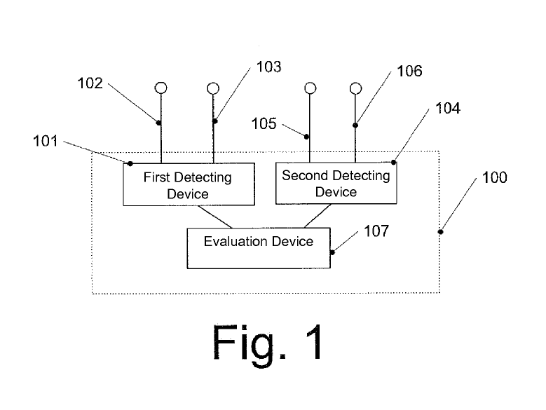

FIG. 1 illustrates a device 100 according to an embodiment. In particular, the illustrated embodiment includes various elements that enable determining a charge at the battery. The device 100 includes a first detecting device 101, with which a charging current of a battery can be detected, and as already explained, a charging current can be positive or negative, depending on whether the battery is charging or discharging. For detecting the charging current, the first detecting device 101 can be coupled to a battery using ports 102 and 103.

In addition, for detecting a voltage of the battery, such as a terminal voltage, the device 100 includes a second detecting device 104. For detecting the voltage of the battery, the second detecting device 104 may be coupled the battery using terminals 105 and 106.

The implementation illustrated in FIG. 1 further includes an evaluation device 107. The evaluation device 107 is arranged to determine a charge state of a battery that is coupled to the device 100. In one example, the evaluation device 107 may determine that the battery is in a charging state or discharging state when an absolute value of a charging current is at or above a first predetermined threshold value.

During a charging or discharging state of a battery, the evaluation device 107 may store information obtained by at least one of the first detecting device 101 and the second detecting device 104. For example, the evaluation device 107 may store the value or values of a charging current obtained by the first detecting device 101. In addition, the evaluation device 107 may store the value or values of a voltage associated with a battery coupled to the second detecting device 104.

In one example, the evaluation device 107 may determine that the battery is in a low current state, e.g. a load coupled to the battery is drawing minimal or no current, when a current detected by the first detecting device 101 is below a second predetermined threshold value that is less than or equal to the first predetermined threshold value.

In one example, typical values for the first predetermined threshold value and the second predetermined threshold value may reside in the range of 1/20 C and 1/30 C, where C represents a capacity rating for a given battery. For example, 1.9 Ah battery is concluded to be rated at 1 C and 1.9 A. A battery may be considered to be in a low current mode when the battery is not supplying significant current to a device coupled to the battery, such as a load. Such a low current mode of a battery may be considered a steady state period or a standby state. In one example, the evaluation device 107 may ascertain the charge state of the battery based on one or more terminal voltages detected by the second detecting device 104. The second detecting device 104 generally is to detect the one or more terminal voltages before it voltage on a terminal of the battery reaches a steady state. Furthermore, the evaluation device 107 may ascertain the charge state of the battery based one or more current values supplied by the first detecting device 101. The first detecting device 101 generally used to detect the one or more current values associated with the battery before the battery reaches a low current mode. Information obtained from the first detecting device 101 and the second detecting device 104 may be used by the device 100 to ascertain a charging state of the battery. Furthermore, such information obtained by the device 100 may be used to augment stored history data that indicates a charging state of a battery over a period of time. Such historical data may be stored by the device 100, or by another storage medium.

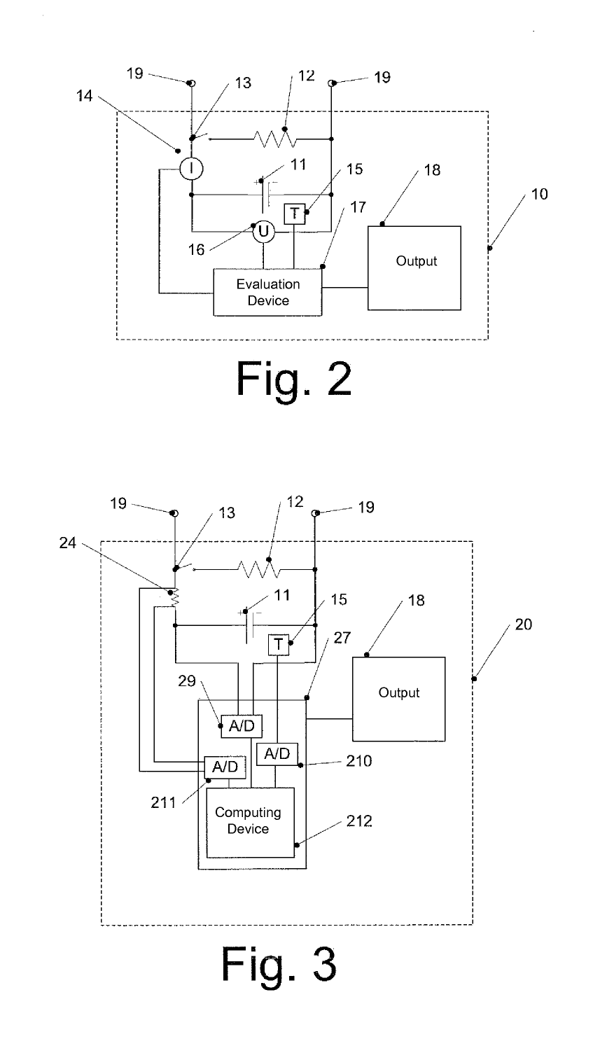

FIG. 2 illustrates a device or apparatus 10 that includes a battery 11. The battery 11 may be a rechargeable lithium battery, or other type of battery. The device 10 may determine a charge state of the battery 11. The device 10 may include electrical components or other such elements that are at least partially powered or enabled by the battery 11. That is, the battery 11 may supply electrical current to the electrical components associated with the device 10. For example, the device 10 may be a mobile device, such as a mobile telephone, a navigation device, or a laptop computer. However, the device 10 is not limited as such. For example, the device 10 may also be a vehicle that includes a battery, or otherwise a stationary device that includes a battery. The battery 11 may be a single cell battery or a multi-cell battery, with the cells of the battery are connected in parallel or series. Furthermore, the battery 11 may be comprised of electrochemical cells. However, it is to be understood that the battery 11 is not so limited.

In one implementation, the battery 11 supplies power (e.g., current and voltage) to a load 12. The load 12 may comprise multiple electrical elements and components. The multiple electronic elements and components of the load 12 may enable the device 10 to function for desired purpose. For example, in one implementation, the load 12 may comprise circuitry that at least partially enables a mobile phone to receive and transmit wireless signals.

The load 12 may be coupled to a switch 13. The switch 13 may be implemented with one or more transistors, such as field effect transistors or bipolar electrical elements. The switch 13 is designed to decouple and coupled the load 12 to the battery 11. This may be desirable when the electrical components associated with the load 12 are not required for use by the device 10. In another example, the switch 13 is not required. For example, the electrical components associated with the load 12 may be configured to enter a standby state in order to reduce the discharge state of the battery 11. In another implementation, the switch 13 may be designed to limit the current drawn by the load 12 in order to achieve a reduced power or standby state of the device 10. In another implementation the battery 11 may be removed from the device 10 and placed in an optional external device for charging.

Two connectors 19 may be associated with the device 10. The connectors 19 enable an external power source to be coupled to the device 10. This external power source may supply a voltage that charges the battery 11.

The embodiment illustrated in FIG. 2 also includes a flowmeter 14, such as a current measuring device. The flowmeter 14 is capable to detect a current flowing from the battery 11. Furthermore, the flowmeter 14 is capable of detecting a current flowing to the battery 11. The indicated currents may be associated with the connectors 19. In one example, the flowmeter 14 is the first detecting device 101 illustrated in FIG. 1. A voltage measuring device 16 may be coupled in parallel with the battery 11. The voltage measuring device 16 is capable of measuring the voltage applied across the battery 100. The voltage applied across the battery 100 may be considered a terminal voltage. In one embodiment, the voltage measuring device 16 is the second detecting device 104 illustrated in FIG. 1. In one example, the voltage measuring device 16 may perform the voltage measurements when the switch 13 is in an open state. Alternatively, the voltage measuring device 16 may perform voltage measurements when the load is in a low current state or otherwise in a standby sleep state. Furthermore, in one implementation, a temperature sensor 15 may be provided. The temperature sensor 15 may be used to measure a temperature of the battery 11. The use of a temperature sensor 15 is optional. Furthermore, the use of the flowmeter 14 is also optional. Furthermore, the temperature sensor 15 may be used to estimate and ambient temperature associated with the battery 11. For example, the temperature sensor 15, in combination with other elements of the device 10, may estimate the ambient temperature associated with the battery 11 based on the temperature of the battery 11.

In one implementation, the combination of the flowmeter 14, the voltage measuring device 16 and the temperature sensor 15 provide information related to the operating conditions of the battery 11. For example, one or more of the foregoing devices may provide information related to the charging and discharging (e.g. for voltage and current) of the battery 11 and information related to the operating temperature of the battery 11.

The flowmeter 14, the voltage measuring device 16 and the temperature sensor 15 may be coupled to an evaluation device 17. The evaluation device 17 is at least capable of receiving a plurality of voltage values from the voltage measuring unit 16. Advantageously, the evaluation device 17 may receive one or more voltage values from the voltage unit 16 before a voltage across the battery 11 reaches a steady-state. In other words, the one or more voltage levels may be obtained by the voltage measuring unit 16 during a period of time that the load 12 transitions to a low current state where the low power state. The detected one or more voltage levels may be used to determine a current charge state to the battery 11. The accuracy of the determined current charge state to the battery 11 may be enhanced from information obtained from at least one of the flowmeter 14 and the temperature sensor 15. Further details and examples of such evaluation are discussed in greater detail hereinafter. The result of the analysis may be displayed to a user of the device 10, for example, optically or acoustically by way of an output 18.

FIG. 3 illustrates a device 20 in accordance with an embodiment. Similar to the device 10, the device 20 may be a mobile device that receives power at least partly from the battery 11. The elements of the device 20 that have the same reference as those associated with the device 10 will not be described again in detail. But as is shown, the device 10 also includes at least the load 12, the temperature sensor 15, an output 18, the switch 13, and the connectors 19. Some or more these elements may be omitted.

The embodiment illustrated in FIG. 3 further includes a resistor 24 coupled in series with the battery 11. In general, the resistor 24 is sized small. For example, the resistor 24 may be 1 ohm or less. The resistor 24 may be coupled to an evaluation device 27. The evaluation device 27 may include an analog-to-digital converter 211 that is coupled to the resistor 24. The analog-to-digital converter 211 is functional to convert a voltage drop across the resistor 24 to a digital value. The voltage drop across the resistor 24 is representative of a charging applied or discharged from the battery 11. A further analog-to-digital converter 29 is provided. The analog-to-digital converter 29 is functional to convert a terminal voltage seen at the terminals of the battery 11 to a digital value.

Furthermore, a voltage level output from the temperature sensor 15 is provided to an analog-to-digital converter 210. The provided voltage level from the temperature 15 represents a temperature of the battery 11. The digital values provided by the analog-to-digital converters 211, 29 and 210 are provided to a computing device 212. As an alternative to the analog-to-digital converters 211, 29 and 210, a single analog-to-digital converter may be provided that accomplishes the functionality provided by the analog-to-digital converters 211, 29 and 210.

The digital information received by the computing device 212 may be used individually or collectively to determine a charge state of the battery 11. This determined charge state may be output to the output device 18. In one implementation, the computing device 212 may be a microcontroller, a programmable gate array, such as a field programmable gate array, a digital signal processor, or other suitable device. In one implementation, the information provided by the analog-to-digital converters 211, 29 and 210 and received from the resistor 24, battery 11 and temperature sensor 15 provide information related to a charge state of the battery 11 substantially at the time that the load 12 is transitioning to a low current state but before the terminal voltage associated with the battery 11 reaches a steady-state.

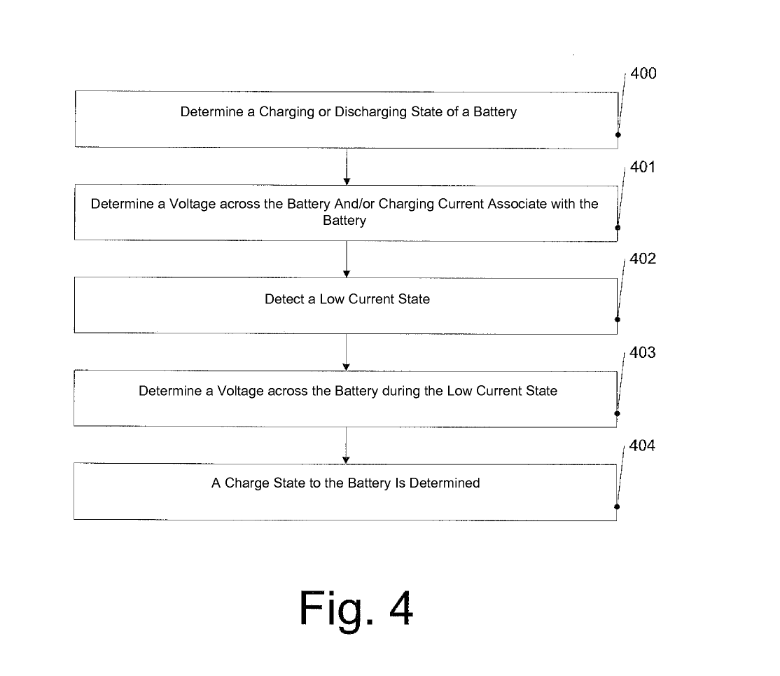

FIG. 4 illustrates a method in flow diagram form according to one embodiment. The method illustrated may be implemented by one or more of the devices illustrated in FIGS. 1-3. Furthermore, the method may be implemented by a device that includes a processor coupled to a tangible storage medium. The tangible storage media may include computer implemented instructions that, when executed by the processor, perform the method illustrated in FIG. 4.

At act 400, a battery is evaluated to determine if it is in a charging or discharging state. For example, a battery may be evaluated to determine if the current is being drawn there from or a current is being delivered thereto. In one particular example, a charging or discharging state of the battery may be determined by comparing a current associated with the battery to a first predetermined threshold.

At act 401, the battery is evaluated to determine if a charging or discharging voltage is being applied to the battery. In addition, the current associated with the battery may be ascertained. The foregoing information may be used to determine if the battery is in a charging or discharging state.

At act 402, a low current state is detected. A low current state may be detected by determining that a current (e.g., a charging current) associated with the battery is below a second predetermined threshold. In one particular embodiment, the second predetermined threshold is less than or equal to the first predetermined threshold. In one particular embodiment, the load current state is indicative of a load associated with the battery being in a standby state, a low power state, or disabled.

At act 403, during a low current state, or otherwise while the load associated or connected with the battery is in a standby state, in low power state or disabled, a terminal voltage (i.e., a voltage across the battery) is detected. Detection of the terminal voltage may occur over a time span and prior to a voltage across the battery reaching a steady-state.

At act 404, a charge state to the battery is determined. The art state to the battery is determined based on some or all of the information gathered during acts 401 and 403. For example, the charge state of the battery may be determined based on a voltage and/or current associated with battery and determined at act 401. Furthermore, the charge state to the battery may be determined based on the detected voltage across the battery. In particular, the charge state of the battery may be determined based on the detected voltage across the battery while the load associated or connected with the battery is in a standby state, in low power state or disabled.

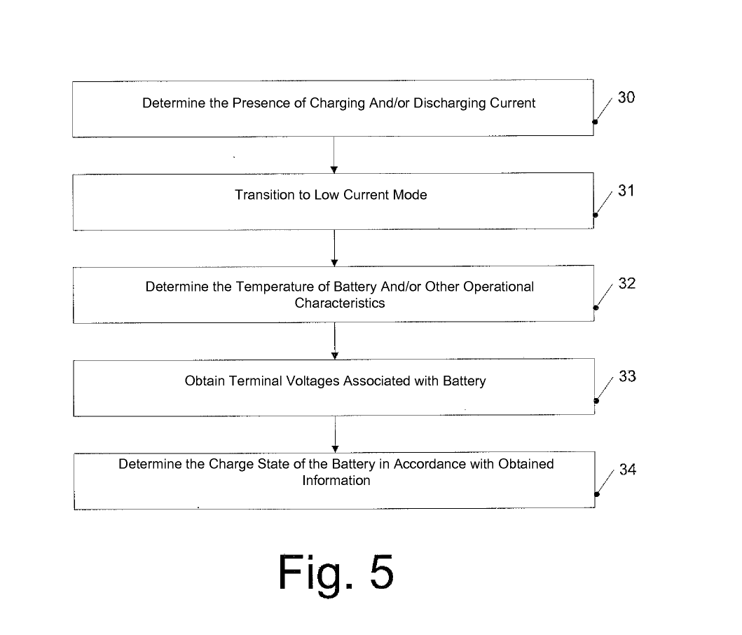

FIG. 5 illustrates a method in flow diagram form according to one embodiment. The method illustrated may be implemented by one or more of the devices illustrated in FIGS. 1-3. Furthermore, the method may be implemented by a device that includes a processor coupled to a tangible storage medium. The tangible storage media may include computer implemented instructions that, when executed by the processor, perform the method illustrated in FIG. 5.

At act 30, a charging and/or discharging of the battery, during the charging and/or discharging of the battery, is determined.

At act 31, a load coupled to the battery is transitioned to a low current mode. In one example, the battery is disconnected from the load, or portion of the load. The node may be transitioned to a low current mode in order to save power, and/or because the load entered a standby or disabled state.

At act 32, the temperature of the battery is detected. Furthermore, at act 32, further operational characteristics of the battery may be detected.

At act 33, a terminal voltage associated with the battery is detected. Multiple terminal voltages may be detected over a period of time. In one implementation, the one or more terminal voltages associated with the battery are detected during a low current state associated with the load. In another implementation, the one or more terminal voltages associated with the battery are detected while a load is substantially disconnected from the battery. The one or more terminal voltages may be detected, one of the time, over a duration of the predetermined timeframe. That predetermined timeframe may be up to a maximum of 45 minutes, or up to 10 minutes after the battery is separated or otherwise disconnected from the load. Generally, it is beneficial to detect the terminal voltages before the battery reaches a steady-state. This generally occurs approximately 60 minutes after the battery is substantially disconnected (i.e., open circuit) from the load.

At act 34, the charge state of the battery is determined based on the one or more voltages sensed in act 33. Furthermore, augmenting information, such as the currents detected at act 30 and the temperature information provided at act 32, may be used to improve the fidelity of the determined charge state to the battery.

The method illustrated in FIGS. 4 and 5 may be combined together. Furthermore, various acts associated with methods may be omitted or combined together. In one example, the acts of 30, 32 and 33 may be performed simultaneously and/or continuously.

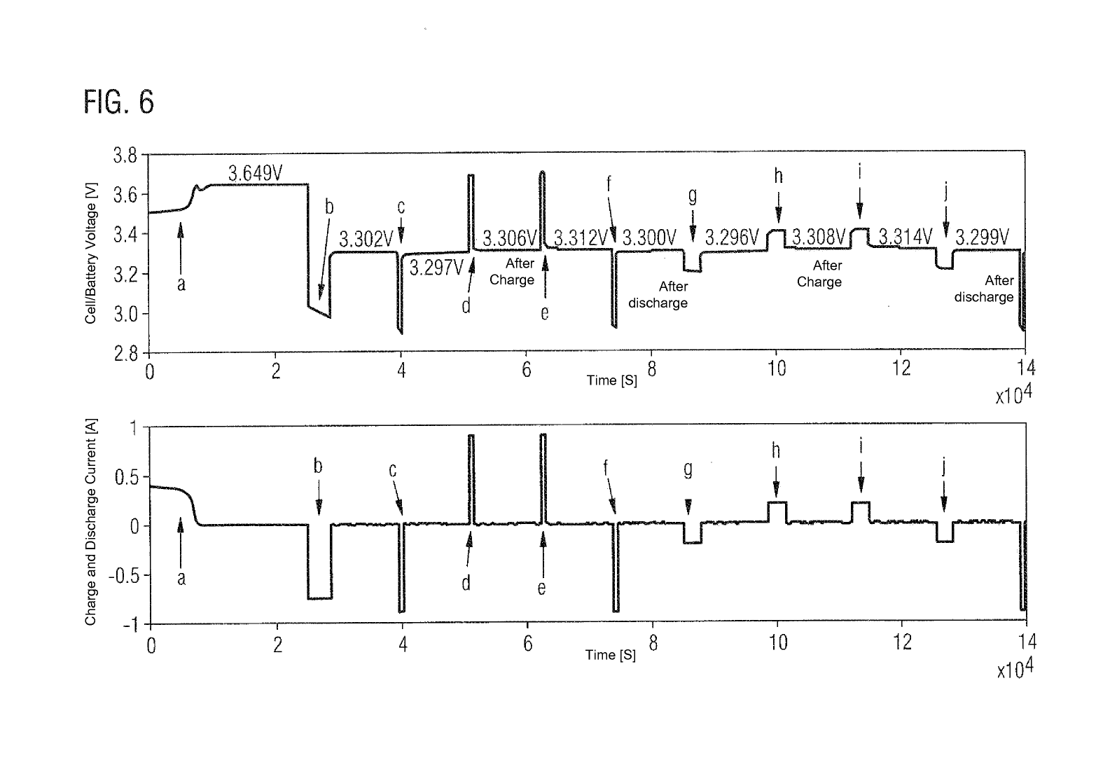

FIG. 6 illustrates graphs that show an influence of a terminal voltage over time. The upper graph of the figure illustrates a cell voltage plotted against time. The upper graph of the figure illustrates a charge or discharge of the battery against time. The battery used for the graphs shown in the figure had a capacity of 1500 mAh. At the beginning of the measurement period, the battery was charged to 50% of its maximum capacity, where 0% represents a full charge to the battery and 100% corresponds to a full discharge of the battery.

At “a” in FIG. 6, the battery is charged to a full level (0% discharge level) followed by a three-hour relaxation to a steady-state. At “b”, the battery is discharged to the 50% discharge point, followed by a three-hour relaxation. The discharge current used is 0.5 C. At “c”, the battery is discharged to the 60% discharge point, followed by a three-hour relaxation. The discharge current used is 0.6 C. At “d”, the battery is charged to the 50% discharge point, followed by a three-hour relaxation. The charge current used is 0.6 C. At “e”, the battery charged to the 40% discharge point, followed by a three-hour relaxation. The charge current used is 0.6 C. At “f”, the battery is discharged to the 50% discharge point, followed by a three-hour relaxation. The discharge current used is 0.6 C. At “g”−“j”, the foregoing applies, but a charge/discharge currents of 0.13 C are used.

As can be seen, in accordance with the charging and discharging steps b, d, f, h and j, for example, the discharge level of each is 50%. The open circuit voltages after three hours, however, differ slightly. This effect is called the hysteresis effect. This influence is not corrected, but the charging state is determined solely on the basis of the open circuit voltage or determined on the basis of voltage measurements approximating the value of the open circuit voltage and corresponding variations in the charge state result. In addition, different types of batteries have different temperatures at different open circuit voltages. These different temperatures may affect various results.

In general, a terminal voltage of a battery may be written as yk, where

yk=OCV(DOD)−R·ik−U(T)+hk (1),

wherein OCV (DOD) is dependent on the degree of discharge DOD open circuit voltage, R is an internal resistance of the battery, which causes at a particular charge/discharge current ik a voltage drop, U(T) represents a voltage contribution which T depends on a time constant and for example reflects chemical processes such as diffusion, and hk is a hysteresis term, which is a function of different historical charge/discharge currents.

For determining the state of charge of a battery, a suitable function may be chosen which is then adjusted to voltage values measured after disconnecting the battery from the load. A possible description of the timing of the terminal voltage Vt (t), where t is time, is

Vt(t)=Vinf−a·exp(b/t)+t^{c}30 h1+h2. (2)

Vinf, a, b and c are parameters that can be determined by fitting the function of equation (2) to the measured voltage values, h1 and h2 are correction terms which, for example, for hysteresis effects, The initialization of the parameters, for example Vinf, a, b and c can, for example, be on the basis of measured currents flowing for example, while the battery is in a state of charging or discharging, and/or in dependence on other functions, such as the age of the battery and/or the impedance of the battery.

The correction values h1 and h2 may be determined based on the measured currents and/or on the basis of measured temperatures, for example, as well. It should be noted that in some embodiments, only a single correction value can be used and/or only some influences and operating conditions of the battery can be considered. For example, correction values for different preceding charging and discharging for a particular type of battery during a calibration phase can be experimentally determined and then be read during operation in dependence on detected charging and discharging currents from a table. The same is true for different temperature values.

In some embodiments, the equation (2) including the correction values can be adjusted to a measured curve and an approximate value for the steady state open circuit voltage is determined from the equation. In other embodiments, the correction values h1 and h2 may be neglected.

The equation without h1 and h2 may be

log(Vinf−V(t))=log(a)+(b/t)+c·log(t). (3)

With this function, as explained above, fitting may be performed similar to as described above with reference to equation (2), in order to determine the parameters Vinf, a, b and c. A value for V(t) can be extrapolated for any times by certain parameters (possibly neglecting h1 and h2) in equation (2). In embodiments, the time t is selected such that it at least approximately corresponds to a steady-state of the battery.

But use of the foregoing equations, as well as the embodiments presented in connection with FIGS. 1-5, determining an open terminal voltage associated with the battery may be quickly determined compared to processes that require that the terminal voltage associated with the battery approach a steady-state before making the open terminal voltage determination.

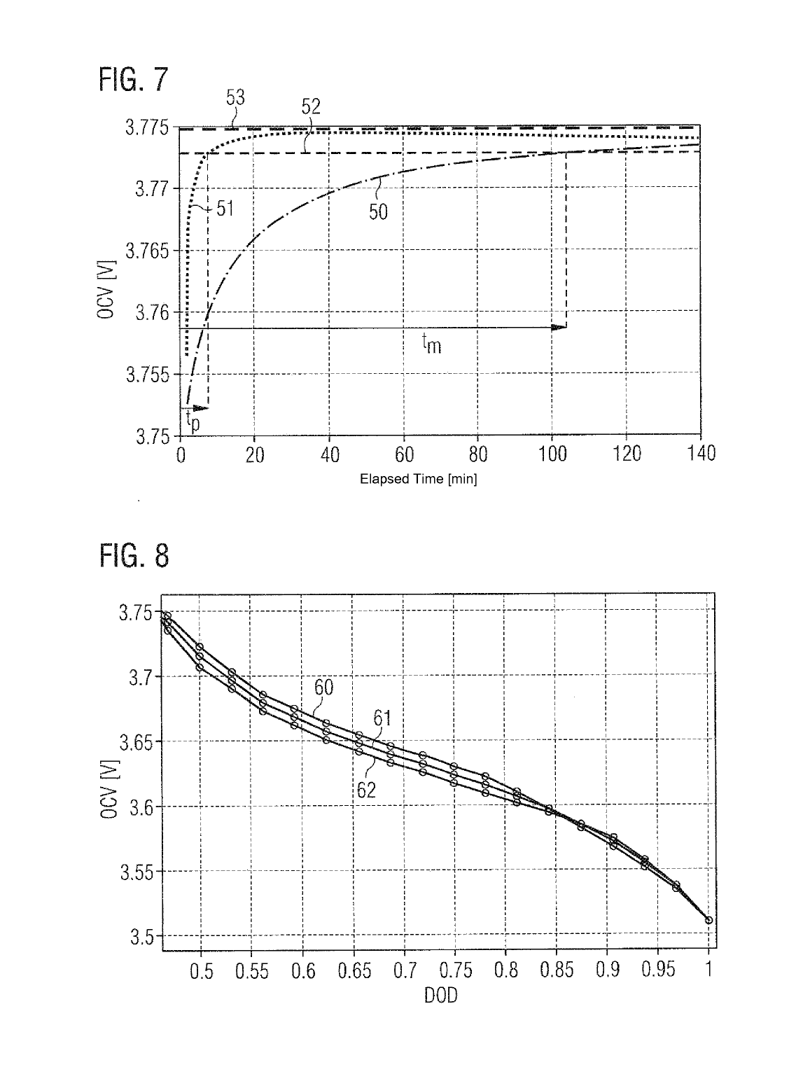

FIG. 7 illustrates a curve 50 that shows a measured open terminal voltage associated with the battery. Curves 52, 53 define a region which results from a value of the open circuit voltage after three hours plus/minus a threshold value, said threshold value representing a desired accuracy of the determination. The open circuit voltage after three hours is used as an example of a measurement of the open circuit voltage, as after three hours a steady-state value is reached. A curve 51 shows an estimate of the open circuit voltage after three hours based on use of the foregoing equations, as well as the embodiments presented in connection with FIGS. 1-5.

As can be noted from FIG. 7, the estimated, in accordance with the implementations described herein, value of the open circuit voltage after a time tₚ of about eight minutes falls within the area bounded by the lines 52 and 53 range, whereas in a pure measurement of the open circuit voltage according to curve 50 occurs after tₘ, a time of more than 100 minutes is the case. Thus, using the embodiments described herein, a value for the open circuit voltage of a desired accuracy can be determined much faster than with a pure measure, such as within a period of time tₚ of 45 minutes or less (e.g. 15 minutes or less, about 8 minutes as presented).

If the open circuit voltage is determined by fitting and neglecting corrections h1 and h2, the state of charge, a discharge degree DOD may then be in accordance

DOD=f(OCV, h1, h2). (4)

The OCV can be approximately determined by fitting using open circuit voltage, h1, for example, on the basis of charging currents (for charging and/or discharging of the battery) of specific correction value, and h2 is a correction value based on the temperature. The values for the discharge OCV level for various values of, for example, h1 and h2 can be stored in a table. An example of a table in which no temperature effects are taken into account (i.e., h2 is not considered), is illustrated below:

| | | h1_charging | h1_charging |
|---|---|---|---|
| DOD [%] | OCV [V] | (0.6 C) [V] | (0.13 C) [V] |
| 50 | 3.301 | 0.011 | 0.011 |
| . . . | . . . | . . . | . . . |
| | | h1_discharging | h1_discharging |
| DOD [%] | OCV [V] | (0.6 C) [V] | (0.13 C) [V] |
| 50 | 3.301 | 0.001 | 0.002 |
| . . . | . . . | . . . | . . . |

As already explained, the temperature can be considered as an additional correction. For illustration, FIG. 8 shows a steady state value of the open circuit voltage OCV as a function of the degree of discharge DOD. In FIG. 8 a discharge rate of 1 corresponds to a discharge rate of 100%, with the curves 60, 61 and 62 showing the relationship for three different temperatures.

The above simulations and graphs are intended to be illustrative, and the exact curves in actual implementations of the illustrated embodiments may deviate from the curves shown depending a particular implementation.

For the purposes of this disclosure and the claims that follow, the terms “coupled” and “connected” have been used to describe how various elements interface. Furthermore, elements and devices described herein may be implemented in hardware or software, or a combination of hardware and software. Such described interfacing of various elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims. The specific features and acts described in this disclosure and variations of these specific features and acts may be implemented separately or may be combined.

1. A method, comprising:
detecting at least one of a charging and discharging state of a battery by determining that an amount of current associated with the battery is above a first predetermined threshold value;
detecting at least one of a voltage and current associated with the battery during the detected at least one of the charging and discharging state;
detecting a low current state by detecting an amount of current associated with the battery is below a second predetermined threshold value, the second predetermined threshold value being less than or equal to the first predetermined threshold value;
detecting a terminal voltage associated with the battery during the low current state and before the terminal voltage associated with the battery reaches a steady-state; and
determining a charge state of the battery based on the detected terminal voltage and further based on the detected at least one of the voltage and current associated with the battery, the determining of the charge state of the battery occurring before the terminal voltage associated with the battery reaches the steady-state.

2. The method according to claim 1, wherein detecting the terminal voltage associated with the battery occurs less than 45 minutes after detecting the low current state.

3. The method according to claim 1, wherein determining the charge state includes extrapolating the detected terminal voltage to determine an approximate steady-state value of the terminal voltage, wherein the determined charge state is based at least in part on the approximate steady-state value of the terminal voltage.

4. The method according to claim 3, wherein the extrapolating includes adapting a function associated with the detected terminal voltage.

5. The method according to claim 4, wherein the function is dependent on the detected at least one of the voltage and current.

6. The method according claim 4, wherein the extrapolating is performed without regard for the detected at least one of the voltage and current, and wherein the charge state is a function of the approximate steady-state value of the terminal voltage and correction values based on the detected at least one of the voltage and current.

7. The method according to claim 6, wherein the approximate steady-state value of the terminal voltage and the correction values are provided in stored table format.

8. The method according to claim 1, wherein the charge state is a function of at least one additional operating characteristic of the battery.

9. The method according to claim 8, wherein the at least one additional operating characteristic of the battery includes at least one of a temperature of the battery and aging information associated with the battery.

10. The method according to claim 8, wherein the at least one additional operating characteristic of the battery includes a temperature surrounding the battery.

11. The method according to claim 10, further comprising detecting a temperature of the battery, and estimating and ambient temperature associated with the battery based on the detected temperature the battery.

12. The method according to claim 11, wherein estimating the ambient temperature further considers the current associated with the battery during the detected at least one of the charging and discharging state.

13. An apparatus, comprising:
a first detecting element to detect a current associated with a battery;
a second detecting element to detect a voltage associated with the battery; and
an evaluation element to detect at least one of a charging and discharging state of the battery when the current detected by the first detecting element is above the first predetermined threshold value, the evaluation element to determine a low current condition associated with a load when the current detected by the first detecting element is less than or equal to a second predetermined threshold value, the second threshold value being less than or equal to the first threshold value, and the evaluation element to determine a charge state of the battery dependent on the voltage provided by the second detecting element during the low current condition associated with the load and before the voltage associated with the battery reaches a steady-state condition, and further dependent on at least one of the detected current and detected voltage.

14. The apparatus according to claim 13, further comprising a temperature sensor to detect at least one of a temperature of the battery and an ambient temperature of the battery, wherein the evaluation element is further adapted to determine the charge state to the battery dependent on the at least one of the temperature the battery and the ambient temperature the battery.

15. The apparatus according to claim 13, wherein the evaluation element comprises a plurality of analog-to-digital converters.

16. The apparatus according to claim 13, wherein detecting the voltage associated with the battery occurs less than 45 minutes after detecting the low current condition.

17. The apparatus according to claim 16, wherein determining the charge state includes extrapolating the detected voltage to determine an approximate steady-state value of the voltage, wherein the determined charge state is based at least in part on the approximate steady-state value of the voltage.

18. The apparatus according to claim 17, wherein the extrapolating includes adapting a function associated with the detected voltage.

19. The apparatus according to claim 18, wherein the function is dependent on the detected at least one of the voltage and current.

20. The apparatus according to claim 17, wherein the extrapolating is performed without regard for the detected at least one of the voltage and current, and wherein the charge status is a function of the approximate steady-state value of the voltage and correction values based on the detected at least one of the voltage and current.

21. The apparatus according claim 20, wherein the approximate steady-state value of the voltage and the correction values are provided in stored table format.

22. The apparatus according to claim 13, wherein the evaluation element is further configured to determine the current charge state as a function of at least one additional operating characteristic of the battery.

23. The apparatus according to claim 22, wherein the at least one additional operating characteristic of the battery includes at least one of a temperature of the battery and aging information associated with the battery.

24. The apparatus according to claim 22, wherein the at least one additional operating characteristic of the battery includes a temperature surrounding the battery.

25. The apparatus according to claim 13, further comprising a temperature sensor to detect a temperature of the battery, the evaluation element to estimate an ambient temperature associated with the battery based on the detected temperature the battery.
